(19) United States
(12) Patent Application Publication
(10) Pub. No.: US 2009/0155401 A1
(43) Pub. Date: Jun. 18, 2009

(54) Method of Forming Nanopattern and Substrate Having Pattern Formed Using the Method

(76) Inventors: Sang-Choll Han, Daejeon Metropolitan City (KR); Seung-Tae Oh, Daejeon Metropolitan City (KR); Deok-Joo Kim, Daejeon Metropolitan City (KR); Matthias Henyk, Daejeon Metropolitan City (KR)

Correspondence Address: MCKENNA LONG & ALDRIDGE LLP, 1900 K STREET, NW, WASHINGTON, DC, 20006, US

(21) Appl. No.: 12/225,690

(22) PCT Filed: Mar. 27, 2007
(86) PCT No.: PCT/KR2007/001495

§ 371 Date: Sep. 26, 2008

(30) Foreign Application Priority Data
Mar. 28, 2006 (KR) 10-2006-0027946
Apr. 11, 2006 (KR) 10-2006-0032655

(51) Int. Cl. G03F 7/20; B32B 3/10; B29D 7/00; B28B 3/12

(52) U.S. Cl. 425/363; 430/325; 430/323; 430/320; 428/195.1; 425/470; 428/187

(57) ABSTRACT

The present invention relates to a method of forming a nanopattern, and, more particularly, to a method of continuously forming a nanopattern in a large area and a method of forming a nanopattern on a substrate having a roll shape, and a substrate having a pattern formed using the method. A method of relatively moving a specimen having a large area and a light source of interfering light and a method of performing exposure through the relative axial movement of the light source of interfering light and the substrate having a roll shape while the substrate having a roll shape rotates are used to avoid the problems occurring in the related art, such as a large space required for the equipment during the formation of nanopatterns, a limited output of a laser, and a limited degree of freedom in patterns.

### TECHNICAL FIELD

The present invention relates to a method of forming a nanopattern, and, more particularly, to a method of continuously forming a nanopattern in a large area and a method of forming a nanopattern on a substrate having a roll shape, and a substrate having a pattern formed using the method.

This application claims priority from Korean Patent Application Nos. 10-2006-27946 and 10-2006-32655 filed on Mar. 28, 2006 and Apr. 11, 2006 in the Korean Intellectual Property Office, the disclosure of which is incorporated herein by reference in its entirety.

### BACKGROUND ART

Generally, in order to form fine patterns on display devices such as semiconductor circuit elements and LCDs or produce stamps to form fine patterns on elements or devices, an optical lithography process using a photosensitive resin (photoresist) is usually used. In the optical lithography process, a photosensitive film provided on a substrate may be selectively exposed and developed to form fine patterns thereon. Examples of a process of selectively exposing the photosensitive film include a process using a mask or a process using light interference.

Recently, the formation of fine patterns has been required in accordance with the rapid development of integrated circuits, and studies have been conducted to reduce the size of the pattern to nanometers. Hereinafter, in the specification, when patterns having a predetermined shape are continuously formed at the intervals of nanometers, that is, 1000 nm or less, they are called nanopatterns. Meanwhile, as the size of the display device is getting bigger, it is necessary to increase the area of the fine pattern.

Generally, ultraviolet rays or laser beams having a shorter wavelength should be used in order to form the patterns of high precision by using a light interference lithography process. However, since there is a limit in printing out the known short wavelength laser, the size of the fine pattern formable by the known laser is, in turn, limited. In the related art, a method of disposing a specimen having a large area and a light source at intervals of several meters is used in order to radiate the laser beam having the short wavelength onto the specimen having a large area. For example, FIG. 2 illustrates the formation of a pattern through light interference. However, the above-mentioned method is problematic in that a large space is required and a large amount of laser beam is absorbed in the air in the case of when the light source having the short wavelength is used to form a pattern of precision. Therefore, in the case of when light having a short wavelength of a predetermined value or less is used, processing may be performed in a vacuum.

Meanwhile, the optical lithography process using a mask is problematic in that the production cost of the mask of the fine pattern is high and it is difficult to produce the mask having a nanopattern. In the light interference lithography process in which the pattern is formed on the specimen by using the light source of interfering light spaced apart from the specimen, there are problems in that the degree of freedom in shaping the pattern is limited and the precision of the pattern is reduced as the distance between the specimen and the light source is increased.

In recent years, a technology of applying a nanoimprint process to the formation of fine patterns in a large area has been studied (Korean Unexamined Patent Application Publication Nos. 2005-37773 and 2005-75580). However, due to the above-mentioned reason, it is difficult to produce stampers large enough for transcription of patterns used in the nanoimprint process. Therefore, in the technology using the nanoimprint process, it is inevitable to simultaneously use a plurality of stampers or repeatedly use the single stamper several times in order to form fine patterns in a large area. In the case of when the fine patterns are formed in a large area by using the known nanoimprint process, fine patterns are not continuously formed in a large area and joints of the patterns that are several tens of micrometers or more in length are generated, which makes it difficult to use for displays.

To sum up, there has not been a case in which the nanopatterns are continuously formed in a large area in the related art. For this, the term “large area” means an area having a predetermined shape where the longest width, for example, the diameter for circles or the diagonal line for rectangles, is more than 12 inches, preferably 20 inches or more, and more preferably 40 inches or more. In current semiconductor chip makers, the maximum size of the wafer used for optical lithography is 12 inches in terms of diameter. In the art, there is a need to develop a method of continuously forming fine patterns in a large area.

### DISCLOSURE OF INVENTION

### Technical Problem

The present inventors have found that a method of relatively moving a specimen having a large area and a light source of interfering light and a method of exposing a substrate having a roll shape through the relative axial movement of the light source of interfering light and the substrate having the roll shape while the substrate rotates are useful to avoid the problems occurring in the related art, such as a large space required for the equipment during the formation of nanopatterns, limited output of a laser, and a limited degree of freedom in patterns. Therefore, an object of the present invention is to provide a method of continuously forming nanopatterns in a large area, a method of forming nanopatterns on a substrate having a roll shape, and a substrate having patterns formed using the methods.

### Technical Solution

In order to accomplish the above object, the present invention provides a method of forming patterns, which includes A) forming a photosensitive resin layer on a substrate, B) selectively exposing the photosensitive resin layer according to the pattern formed by the interfering light by moving relatively the substrate on which the photosensitive resin layer is formed and a light source of interfering light, and C) forming the patterns on the photosensitive resin layer by developing the selectively exposed photosensitive resin layer.

Furthermore, the present invention provides a method of forming patterns, which includes a) forming a photosensitive resin layer on a substrate having a roll shape, b) selectively exposing the photosensitive resin layer according to the patterns formed by the interfering light by moving relatively a light source of interfering light and the substrate having the roll shape in an axial direction of the substrate while the substrate having the roll shape on which the photosensitive resin layer is formed rotates, and c) forming the patterns on the photosensitive resin layer by developing the selectively exposed photosensitive resin layer.

### Advantageous Effects

According to the present invention, it is possible to continuously form nanopatterns in a large area, to improve the degree of freedom and the precision of the nanopattern in comparison with known technology, and to reduce a space for equipment to form patterns in a large area.

### BRIEF DESCRIPTION OF THE DRAWINGS

FIG. 1 illustrates a mechanism of forming a pattern by using light interference;

FIG. 2 is a layout illustrating a patterning process using light interference;

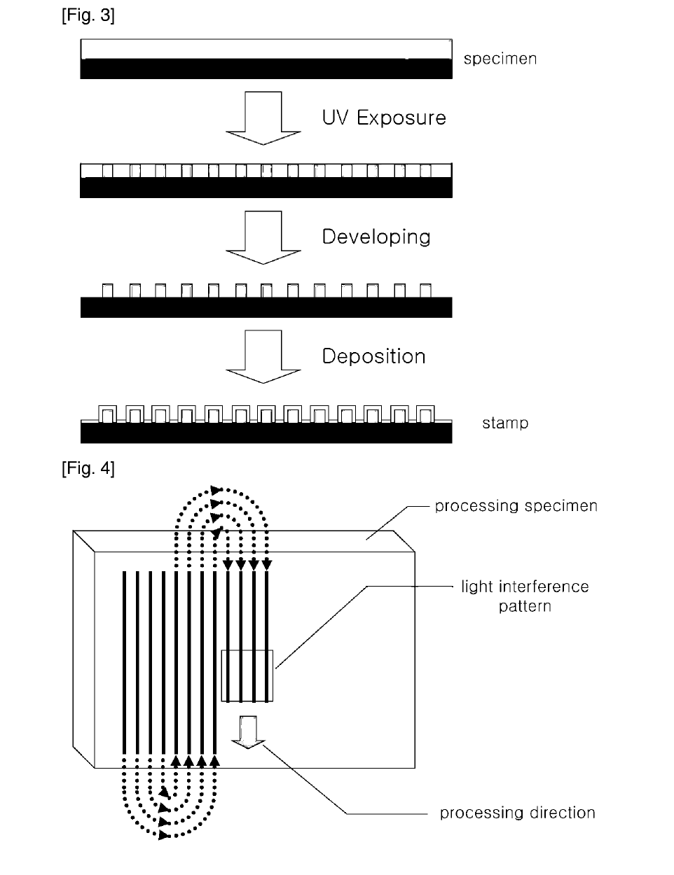

FIG. 3 illustrates the production of a stamp;

FIGS. 4 to 6 are views illustrating the formation of patterns through relative movement of a substrate and a light source according to an embodiment of the present invention;

FIGS. 7 to 9 are views illustrating the formation of patterns through relative movement of a substrate having a roll shape and a light source while the substrate having a roll shape rotates according to an embodiment of the present invention; and

FIGS. 10 to 12 illustrate different types of interfering light heads.

### BEST MODE FOR CARRYING OUT THE INVENTION

The present invention provides a method of forming patterns, which includes A) forming a photosensitive resin layer on a substrate, B) selectively exposing the photosensitive resin layer according to the pattern formed by the interfering light by moving relatively the substrate on which the photosensitive resin layer is formed and a light source of interfering light, and C) forming the patterns on the photosensitive resin layer by developing the selectively exposed photosensitive resin layer.

The method may further include D) selectively etching the substrate by using the patterned photosensitive resin layer, and E) removing the photosensitive resin layer.

The method may further include D′) producing a mold through plating of the patterned photosensitive resin layer and separation of a plated portion from the substrate having the photosensitive resin layer, and E′) transferring nanopatterns by using the mold.

Furthermore, the present invention provides a substrate, on at least one side of which photosensitive resin patterns are continuously formed in an area having a longest width of more than 12 inches at intervals of nanometers or less by using the method including steps A, B, and C. The area in which the patterns are formed has the longest width of preferably 20 inches or more, and more preferably 40 inches or more.

Furthermore, the present invention provides a substrate, on which patterns are continuously formed in an area having a longest width of more than 12 inches at intervals of nanometers or less by using the method including steps A, B, C, D, and E or steps A, B, C, D′, and E′. The area in which the patterns are formed has the longest width of preferably 20 inches or more, and more preferably 40 inches or more.

Furthermore, the present invention provides a mold, on which patterns are continuously formed in an area having a longest width of more than 12 inches at intervals of nanometers or less by using the method including steps A, B, C, and D′. The area in which the patterns are formed has the longest width of preferably 20 inches or more, and more preferably 40 inches or more.

Furthermore, the present invention provides an electronic element, an electronic device, or a stamper including nanopatterns formed using the above-mentioned method. The electronic element may be a beam splitting polarizer, and the electronic device may be a display device.

Furthermore, the present invention provides a method of forming patterns, which includes a) forming a photosensitive resin layer on a substrate having a roll shape, b) selectively exposing the photosensitive resin layer according to the patterns formed by the interfering light by moving relatively a light source of interfering light and the substrate having the roll shape in an axial direction of the substrate while the substrate having the roll shape on which the photosensitive resin layer is formed rotates, and c) forming the patterns on the photosensitive resin layer by developing the selectively exposed photosensitive resin layer.

The method may further include d) selectively etching the substrate having the roll shape by using the patterned photosensitive resin layer, and e) removing the photosensitive resin layer.

The method may further include d′) producing a mold through plating of the patterned photosensitive resin layer and separation of a plated portion from the substrate having the photosensitive resin layer, and e′) transferring nanopatterns by using the mold.

Furthermore, the present invention provides a substrate having a roll shape, on at least one side of which photosensitive resin patterns are continuously formed in an area having a longest width of more than 12 inches at intervals of nanometers or less by using the method including steps a, b, and c. The area in which the patterns are formed has the longest width of preferably 20 inches or more, and more preferably 40 inches or more.

Furthermore, the present invention provides a substrate having a roll shape, on which patterns are continuously formed in an area having a longest width of more than 12 inches at intervals of nanometers or less by using the method including steps a, b, c, d, and e or steps a, b, c, d′, and e′. The area in which the patterns are formed has the longest width of preferably 20 inches or more, and more preferably 40 inches or more.

Furthermore, the present invention provides a mold, on which patterns are continuously formed in an area having a longest width of more than 12 inches at intervals of nanometers or less by using the method including steps a, b, c, and d′. The area in which the patterns are formed has the longest width of preferably 20 inches or more, and more preferably 40 inches or more.

Furthermore, the present invention provides an electronic element, an electronic device, or a stamper including nanopatterns formed using the above-mentioned method. The electronic element may be a beam splitting polarizer, and the electronic device may be a display device.

Furthermore, the present invention provides a method of producing a stamper, the method further including d″) depositing metal such as Cr or a Cr alloy on the photosensitive resin patterns after step c, and a stamper produced using the method.

### Mode for the Invention

A detailed description of the present invention will be given in detail hereinafter.

One of the methods of forming patterns according to the present invention is to form the patterns by using optical lithography, in which interfering light is used to pattern a photosensitive resin layer, and a light source of interfering light and a substrate where the photosensitive resin layer is formed are relatively moved during the exposure of the photosensitive resin layer.

In another method of forming patterns according to the present invention, interfering light is used to pattern a photosensitive resin layer, and a light source of interfering light and a substrate having a roll shape where the photosensitive resin layer is formed are relatively moved in an axial direction of the substrate while the substrate having a roll shape rotates during the exposure of the photosensitive resin layer.

In the present invention, the nanopatterns may be formed using the interfering light. Furthermore, during the exposure, the light source and the substrate on which the photosensitive resin layer is formed may be relatively moved to continuously form the patterns in a large area while the light source and the substrate are positioned closer to each other in comparison with known technology. In the case of when the substrate having a roll shape is used, realization of a large area is easily ensured as long as the length of the roll is increased, and, during the exposure, the light source of the interfering light and the substrate having a roll shape are relatively moved in an axial direction of the substrate while the substrate having the roll shape rotates so as to be positioned closer to each other in comparison with the known technology and to continuously provide spiral patterns around the roll having a large area.

That is, in the related art, the specimen having the large area and the light source are disposed at an interval of several meters in order to radiate the light source onto the substrate having a large area. However, in the present invention, the light source and the plate type substrate (or the substrate having the roll shape) are relatively moved in order to continuously form the patterns in a large area while the light source and the substrate are disposed close to each other.

Therefore, it is possible to reduce a space for equipment to form patterns in a large area in comparison with the known technology. Additionally, since the distance between the light source and the substrate is short, it is possible to improve the precision of patterns formed in a large area. Once the desirable precision is ensured during the processing of the patterns, it is possible to precisely control the patterns by using light having the wavelength that is similar to the short wavelength.

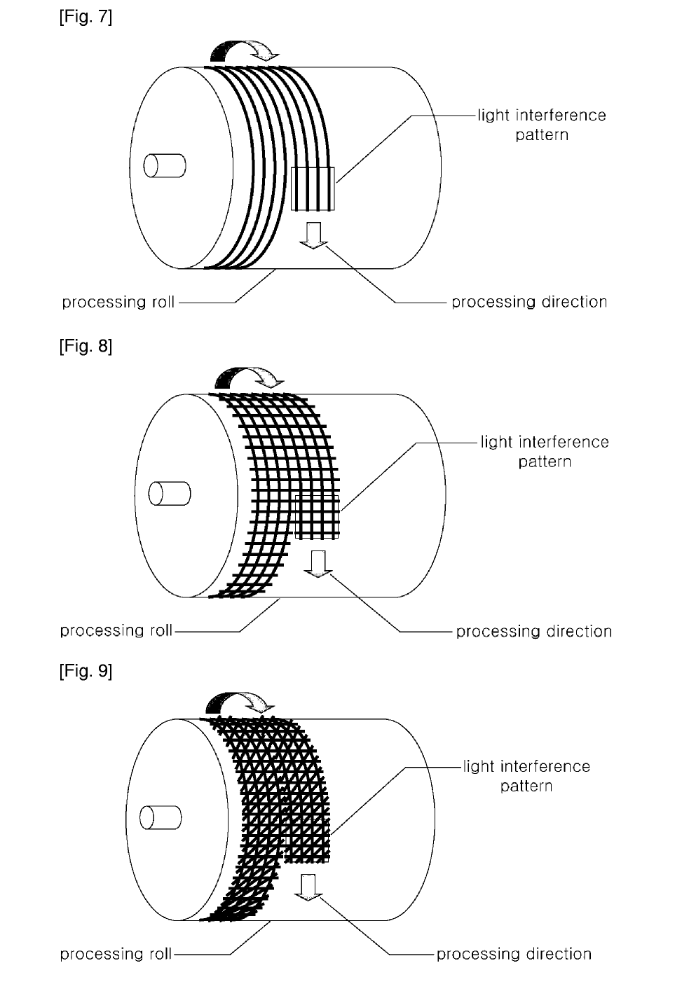

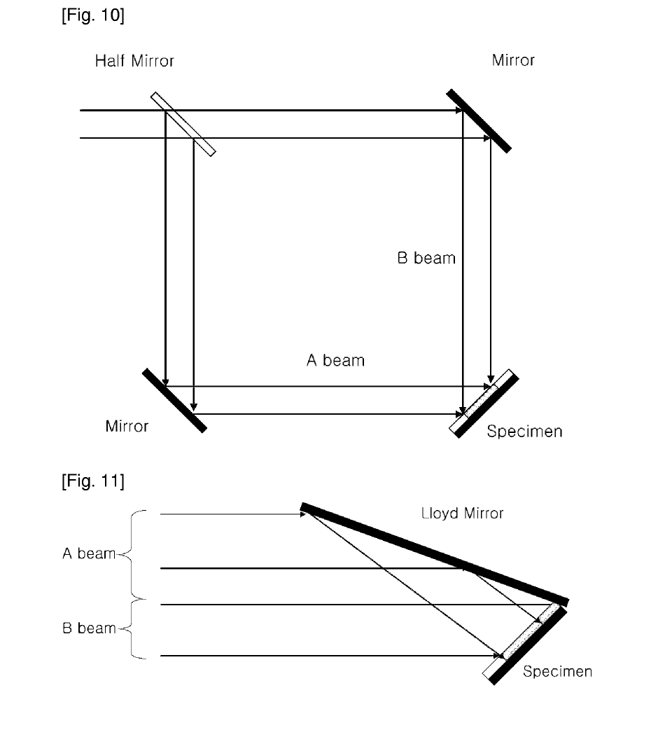

Furthermore, since the distance between the light source and the substrate is short, multi-interference is easily performed, and rotation or reciprocation of the beam head may be ensured. Therefore, since various types of patterns can be formed, it is possible to overcome the limitation of shaping patterns in the known method. For example, in the method of the present invention, various types of patterns can be obtained from multi-interference such as the case of FIGS. 4 and 7 where two beam interferences are used and the case of FIGS. 5 and 8 where four beam interferences are used.

The present invention may be applied to any field where highly precise patterns should be continuously formed in a large area. The substrate having a roll shape where fine patterns are formed according to the method of the present invention may be used without modification or may be used after the substrate is processed to have a plate shape by using the known method depending on the purpose of use. For example, the present invention may be applied to AG (anti-glare)/AR (anti-reflection)/LR (low reflection) films, water-resistant/resistive films, brightness enhancement films, anisotropic films, polarizing films, self cleaning devices, solar cells, high volume holographic memories, photonic crystal, field emission display (FED) electrodes, stampers to transfer highly precise patterns, and the like.

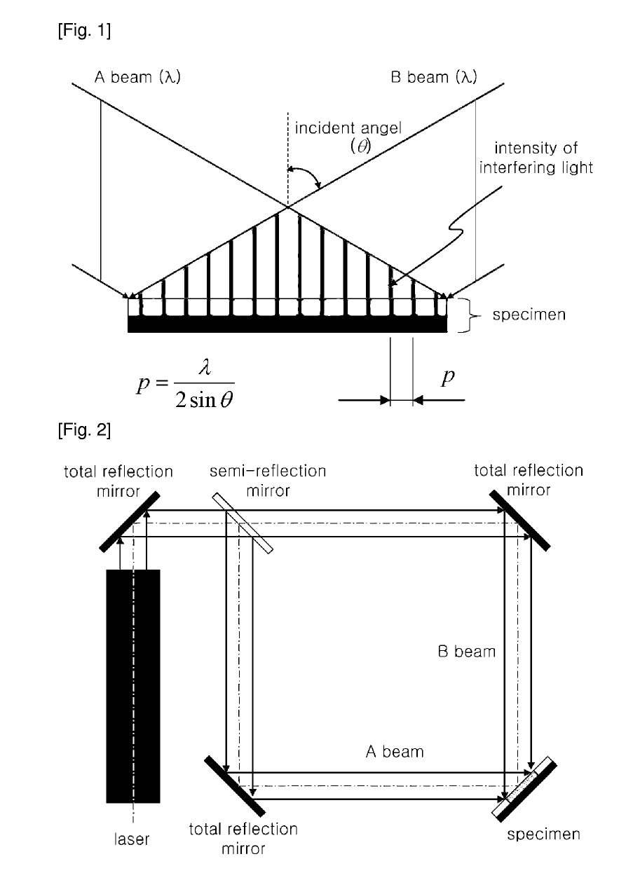

A mechanism of forming the patterns by using light interference according to the present invention is illustrated in FIG. 1. In FIG. 1, λ is a wavelength of light, θ is an incident angle of the light source, and p is a pitch between the patterns formed by the interference of beams from two light sources. The pitch between the patterns is calculated using the following Equation 1.

### [Equation 1]

p=λ/(2sinθ)

Therefore, in the present invention, the number and the type of light sources, the incident type of light, and the angle between light sources which are to be interfered may be controlled to determine the shape and size of a pattern. In the present invention, light having the ultraviolet ray region (193 to 351 nm) may be used as the light source. In the present invention, the type of light source may be determined according to the type of photosensitive resin and the type of photosensitive resin may be determined according to the type of light source.

In the case of when the patterns to be formed have one dimensional shape, as shown in FIG. 4, the patterns may be continuously formed in a large area by the relative movement of the specimen and the light source. In the case of the roll substrate, if the patterns to be formed have one dimensional shape, as shown in FIG. 7, the light source and the substrate having a roll shape may be relatively moved in the axial direction of the substrate while the substrate having a roll shape rotates to continuously provide spiral patterns around the roll.

In the case of when the patterns to be formed have a simple two- or three-dimensional shape, as shown in FIG. 5, the degree of transverse interference may be reduced and the pulsing of horizontal interference may be obtained through synchronization along with the longitudinal cycle of shape to form the patterns. In the case of the roll substrate, as shown in FIG. 8, the degree of axial interference regarding the rotation of the substrate may be reduced and the pulsing may be obtained through synchronization along with the circumferential cycle of the shape of the substrate to form the patterns.

As for more complicated shapes, as shown in FIGS. 6 and 9, a stamping method which is typically used during the semiconductor process, that is, a method of repeating processing and transportation to perform etching without the occurrence of joints, may be performed. Particularly, the light source should be blocked using a shutter or a chopper during the transportation.

In the present invention, the method of relatively moving the light source of the interfering light and the substrate on which the photosensitive resin layer is formed is not limited. As shown in FIG. 4, the method according to the embodiment of the present invention may include B1) radiating interfering light onto the photosensitive resin layer by moving relatively the substrate on which the photosensitive resin layer is formed in respect to the light source, and B2) relatively moving the light source in respect to the substrate so that the light source is radiated onto the photosensitive resin layer not exposed in step B1. Steps B1 and B2 are repeated. In step B1, the substrate moves in the longitudinal direction, and, in step B2, the substrate moves in the transverse direction.

As shown in FIG. 7, the method according to another embodiment of the present invention may include b1) radiating interfering light onto the photosensitive resin layer by moving relatively the roll substrate on which the photosensitive resin layer is formed in respect to the light source, and b2) relatively moving the substrate in respect to the light source in an axial direction so that the light source is radiated onto the photosensitive resin layer not exposed in step b1. Steps b1 and b2 are repeated. In step b1, the substrate moves in the longitudinal direction, and, in step b2, the substrate moves in the transverse direction.

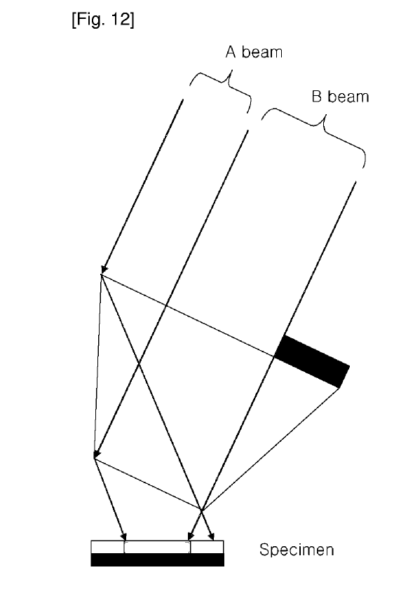

In still another embodiment of the present invention, the interfering light head may rotate or reciprocate to provide various types of patterns. In the present invention, a half mirror, a Loyd mirror, and a prism shown in FIGS. 10 to 12 may be used as an interfering light head, but the interfering light head is not limited thereto. If the prism head shown in FIG. 12 rotates, a concentric circular structure, that is, a Fresnel lens structure, may be obtained.

In the present invention, any material may be used as a material constituting the photosensitive resin as long as the material can be applied to an optical lithography process in the related art, and examples of such material may include SU-6 and SU-8 which are manufactured by Microchem, Corp. The method of forming a photosensitive resin layer on the substrate by using a photosensitive resin is not limited, and any method known in the related art may be used. For example, SU-8 photosensitive resin is applied on the substrate, UV is radiated onto the substrate on which the resin is applied, and the resulting substrate is developed using an organic solvent such as PGMEA (Propylene Glycol Monomethyl Ether Acetate), GBL

(Gamma-Butyrolactone), and MIBK (Methyl Iso-Butyl Ketone) to form the patterns.

In the present invention, the substrate having a roll shape on which the photosensitive resin layer is formed may be hollow or full. The target material of the substrate may be applied on a supporter having a roll shape to produce a roll substrate.

In the present invention, the material of the substrate on which the photosensitive resin layer is formed may be determined according to the purpose of its use. For example, in the case of when the substrate provided with the finely patterned photosensitive resin layer is to be applied to AG (anti-glare)/AR (anti-reflection)/LR (low reflection) films, water-resistant/resistive films, brightness enhancement films, anisotropic films, or polarizing films, optically transparent materials, for example, glass, quartz, or transparent resin, may be used as a material for the substrate. Furthermore, in the case of when fine patterns are to be formed on the substrate by using the photosensitive resin layer patterned through the above-mentioned procedure, a material capable of being selectively etched with an etching solution known in the art, for example, metal material, may be used as the material of the substrate. For example, in the case of when the substrate having patterns formed through the above-mentioned procedure is to be used as a stamper, glass or quartz may be used as a material for the substrate.

According to the method including steps A, B, and C, a substrate, on at least one side of which photosensitive resin patterns are continuously formed in an area having the longest width of more than 12 inches at intervals of nanometers or less, may be provided. Furthermore, according to the method including steps a, b, and c, a substrate, on at least one side of which photosensitive resin patterns are continuously formed in an area having the longest width of more than 12 inches at intervals of nanometers or less and which has a roll shape, may be provided.

In this case, the longest width of the pattern formation area is preferably 20 inches or more, and more preferably 40 inches or more. The substrate or the substrate having a roll shape on which the photosensitive resin patterns having the nanometer size are formed may be applied to AG (anti-glare)/AR (anti-reflection)/LR (low reflection) films, water-resistant /resistive films, brightness enhancement films, anisotropic films, or polarizing films, and the above-mentioned films may be applied to display devices.

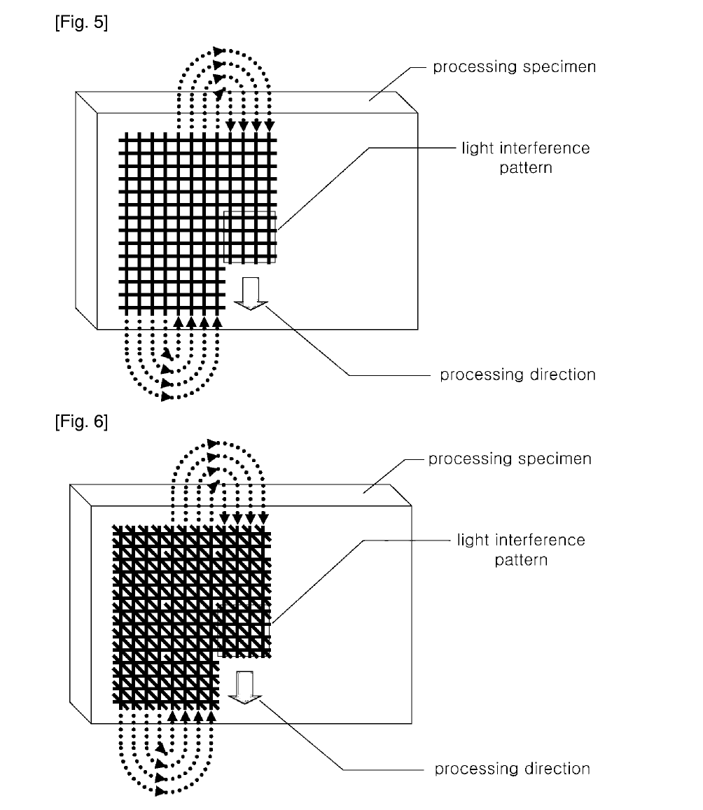

The method of the present invention may further include D″) depositing metal such as Cr or a Cr alloy after step C, and the substrate that is produced using the method may be used as a stamper. The process of producing a stamp is illustrated in FIG. 3.

The method of forming patterns according to the method of the present invention may further include D) selectively etching the substrate by using the patterned photosensitive resin layer and e) removing the photosensitive resin layer.

In order to selectively etch the substrate according to the patterns of the photosensitive resin layer, an etching process and etching agent known in the art may be used. For example, the substrate may be selectively etched through immersing in a solvent such as PGMEA (Propylene Glycol Monomethyl Ether Acetate).

According to the above-mentioned method which includes steps A, B, C, D, and E or the above-mentioned method which includes steps A, B, C, D′, and E′, a substrate, on which patterns are continuously formed in an area having the longest width of more than 12 inches at intervals of nanometers or less, may be provided. The longest width of the area where the patterns are formed is preferably 20 inches or more, and more preferably 40 inches or more. The substrate on which the nanopatterns are formed may be applied to AG (anti-glare)/AR (anti-reflection)/LR (low reflection) films, water-resistant/resistive films, brightness enhancement films, anisotropic films, polarizing films, self cleaning devices, solar cells, high volume holographic memories, photonic crystal, field emission display (FED) electrodes, and stampers to transfer highly precise patterns.

The method of forming patterns according to the present invention may further include D′) performing plating of the patterned photosensitive resin layer and separating the plated portion from the substrate having a photosensitive resin layer to produce a mold, and E′) transferring the nanopatterns by using the mold.

The plating of step D′ may be performed using a process known in the art, for example, an electroplating process. In this connection, nickel or aluminum may be used as a material for the plating. The transcription of patterns of step E′ may be performed using a process known in the art. For example, a curable resin is pressed on the mold and cured by heating or light and then the mold is separated from the resin layer to transfer the patterns.

According to the above-mentioned method which includes steps A, B, C, and D′, a mold, on which patterns are continuously formed in an area having the longest width of more than 12 inches at intervals of nanometers or less, may be provided. The longest width of the area where the patterns are formed is preferably 20 inches or more, and more preferably 40 inches or more. Furthermore, the patterns may be transferred using the mold to produce films on which the fine patterns are to be formed, for example, AG (anti-glare)/AR (anti-reflection)/LR (low reflection) films, water-resistant/resistive films, brightness enhancement films, anisotropic films, or polarizing films, in large quantities. The mold may be semi-permanently used according to the type of material constituting the mold.

Another method of the present invention may further include d″) depositing metal such as Cr or a Cr alloy on the photosensitive resin pattern after step C, and the substrate having a roll shape which is produced using the method may be used as a stamper having a roll shape.

In order to selectively etch the substrate having a roll shape according to the patterns of the photosensitive resin layer, an etching process and etching agent known in the art may be used. For example, the substrate having a roll shape may be selectively etched through immersing in a solvent such as PGMEA (Propylene Glycol Monomethyl Ether Acetate).

According to the above-mentioned method which includes steps a, b, c, d, and e or the above-mentioned method which includes steps a, b, c, d′, and e′, a substrate having a roll shape, on which patterns are continuously formed in an area having the longest width of more than 12 inches at intervals of nanometers or less, may be provided. The longest width of the area where the patterns are formed is preferably 20 inches or more, and more preferably 40 inches or more. The substrate having a roll shape on which the nanopatterns are formed may be applied to AG (anti-glare)/AR (anti-reflection)/LR (low reflection) films, water-resistant/resistive films, brightness enhancement films, anisotropic films, polarizing films, self cleaning devices, solar cells, high volume holographic memories, photonic crystal, field emission display (FED) electrodes, and stampers to transfer highly precise patterns.

The method of forming patterns according to the present invention may further include d′) performing plating of the patterned photosensitive resin layer and separating the plated portion from the substrate having a roll shape and the photosensitive resin layer to produce a mold, and e′) transferring the nanopatterns by using the mold.

The plating of step d′ may be performed using a process known in the art, for example, an electroplating process. In this connection, nickel or aluminum may be used as a material for the plating. The transcription of patterns of step e′ may be performed using a process known in the art. For example, a curable resin is pressed on the mold and cured by heating or light and then the mold is separated from the resin layer to transfer patterns.

According to the above-mentioned method which includes steps a, b, c, and d′, a mold, on which the patterns are continuously formed in an area having the longest width of more than 12 inches at intervals of nanometers or less, may be provided. The longest width of the area where the patterns are formed is preferably 20 inches or more, and more preferably 40 inches or more. Furthermore, the patterns may be transferred using the mold to produce films on which the fine patterns are to be formed, for example, AG (anti-glare)/AR (anti-reflection)/LR (low reflection) films, water-resistant/resistive films, brightness enhancement films, anisotropic films, or polarizing films, in large quantities. The mold may be semi-permanently used according to the type of material constituting the mold.

According to the present invention, nanopatterns are continuously formed in a large area having the longest width of more than 12 inches, preferably 20 inches or more, and more preferably 40 inches or more. In current semiconductor chip makers, the maximum size of the wafer used for optical lithography is 12 inches in terms of diameter, and there has never been a case that the nanopatterns are continuously formed in the large area having the diameter or diagonal line of more than 12 inches.

Nanopatterns which are formed according to the above-mentioned method may be applied to electronic elements or electronic devices and used as a stamper. Examples of the electronic elements include a beam splitting polarizer, and examples of the electronic devices include display devices.

1. A method of forming patterns, the method comprising:
A) forming a photosensitive resin layer on a substrate;
B) selectively exposing the photosensitive resin layer according to the pattern formed by the optical interference by moving relatively the substrate on which the photosensitive resin layer is formed and a light source for interference; and
C) forming the patterns on the photosensitive resin layer by developing the selectively exposed photosensitive resin layer.

2. The method as set forth in claim 1, wherein step B comprises:
B1) illuminating the interfering light onto the photosensitive resin layer by moving relatively the substrate on which the photosensitive resin layer is formed in respect to the light source; and
B2) relatively moving the light source in respect to the substrate so that the light source is illuminated onto the photosensitive resin layer not exposed in step B1,
wherein steps B1 and B2 are repeated.

3. The method as set forth in claim 1, further comprising:
D) selectively etching the substrate by using the patterned photosensitive resin layer.

4. The method as set forth in claim 3, further comprising:
E) removing the photosensitive resin layer.

5. The method as set forth in claim 1, further comprising:
D′) producing a mold through plating of the patterned photosensitive resin layer and separation of a plated portion from the substrate having the photosensitive resin layer.

6. The method as set forth in claim 5, further comprising:
E′) transferring nanopatterns by using the mold.

7. A substrate, on at least one side of which photosensitive resin patterns are continuously formed in an area having a longest width of more than 12 inches at pitches of nanometers or less by using the method of claim 1.

8. (canceled)

9. A substrate, on which patterns are continuously formed in an area having a longest width of more than 12 inches at pitches of nanometers or less by using the method of claim 4.

10. (canceled)

11. A mold, on which patterns are continuously formed in an area having a longest width of more than 12 inches at pitches of nanometers or less by using the method of claim 5.

12. (canceled)

13. An electronic element, on which patterns are formed in an area having a longest width of more than 12 inches at pitches of nanometers or less by using the method according to claim 1.

14. The electronic element as set forth in claim 13, wherein the electronic element is a beam splitting polarizer.

15. An electronic device, on which patterns are formed in an area having a longest width of more than 12 inches at pitches of nanometers or less by using the method according to claim 1.

16. The electronic device as set forth in claim 15, wherein the electronic device is a display device.

17. A method of producing a stamper, the method comprising:
A) forming a photosensitive resin layer on a substrate;
B) selectively exposing the photosensitive resin layer according to the pattern formed by the interfering light by moving relatively the substrate on which the photosensitive resin layer is formed and a light source for interference;
C) forming the patterns on the photosensitive resin layer by developing the selectively exposed photosensitive resin layer; and
D″) depositing metal on the photosensitive resin patterns.

18. The method as set forth in claim 17, wherein the metal of step D″ is Cr or a Cr alloy.

19. A stamper, on which patterns are formed in an area having a longest width of more than 12 inches at pitches of nanometers or less by using the method of claim 17.

20. A method of forming patterns, the method comprising:
a) forming a photosensitive resin layer on a substrate having a roll shape;
b) selectively exposing the photosensitive resin layer according to the patterns formed by the interfering light by moving relatively a light source for interference and the substrate having the roll shape in an axial direction of the substrate while the substrate having the roll shape on which the photosensitive resin layer is formed rotates; and
c) forming the patterns on the photosensitive resin layer by developing the selectively exposed photosensitive resin layer.

21. The method as set forth in claim 20, further comprising:
d) selectively etching the substrate having the roll shape by using the patterned photosensitive resin layer.

22. The method as set forth in claim 21, further comprising:
e) removing the photosensitive resin layer.

23. The method as set forth in claim 20, further comprising:
d′) producing a mold through plating of the patterned photosensitive resin layer and separation of a plated portion from the substrate having the photosensitive resin layer and the roll shape.

24. The method as set forth in claim 23, further comprising:
e′) transferring nanopatterns by using the mold.

25. A substrate having a roll shape, on which photosensitive resin patterns are continuously formed in an area having a longest width of more than 12 inches at pitches of nanometers or less by using the method of claim 20.

26. (canceled)

27. A substrate having a roll shape, on which patterns are continuously formed in an area having a longest width of more than 12 inches at pitches of nanometers or less by using the method of claim 22.

28. (canceled)

29. A mold, on which patterns are continuously formed in an area having a longest width of more than 12 inches at pitches of nanometers or less by using the method of claim 23.

30. (canceled)

31. An electronic element, on which patterns are formed in an area having a longest width of more than 12 inches at pitches of nanometers or less by using the method according to claim 20.

32. The electronic element as set forth in claim 31, wherein the electronic element is a beam splitting polarizer.

33. An electronic device, on which patterns are formed in an area having a longest width of more than 12 inches at pitches of nanometers or less by using the method according to claim 20.

34. The electronic device as set forth in claim 33, wherein the electronic device is a display device.

35. A method of producing a stamper having a roll shape, the method comprising:
a) forming a photosensitive resin layer on a substrate having a roll shape;
b) selectively exposing the photosensitive resin layer according to the patterns formed by the interfering light by moving relatively a light source for interference and the substrate having the roll shape in an axial direction of the substrate while the substrate having the roll shape on which the photosensitive resin layer is formed rotates;
c) forming the patterns on the photosensitive resin layer by developing the selectively exposed photosensitive resin layer; and
d″) depositing metal on the photosensitive resin patterns.

36. The method as set forth in claim 35, wherein the metal of step d″ is Cr or a Cr alloy.

37. A stamper having a roll shape, on which patterns are formed in an area having a longest width of more than 12 inches at pitches of nanometers or less by using the method according to claim 35.
